(19) United States
(12) Patent Application Publication
(10) Pub. No.: US 2006/0003087 A1
(43) Pub. Date: Jan. 5, 2006

(54) Process for producing plasma display panel and apparatus therefor

(75) Inventors: Michihiko Takase, Nara (JP); Yoshinao Oe, Kyoto (JP)

Correspondence Address: WENDEROTH, LIND & PONACK, L.L.P., 2033 K STREET N. W., SUITE 800, WASHINGTON, DC, 20006-1021, US

(73) Assignee: Matsushita Electric Industrial Co., Ltd., Osaka (JP)

(21) Appl. No.: 10/532,673

(22) PCT Filed: Jul. 14, 2004
(86) PCT No.: PCT/JP04/10356

§ 371 Date: Apr. 26, 2005

(30) Foreign Application Priority Data
Jul. 15, 2003 (JP) 2003-197159

(51) Int. Cl. H01J 9/00; H01J 9/24; C23C 16/00

(52) U.S. Cl. 427/64; 445/24; 118/715

(57) ABSTRACT

A method for depositing a high quality metal oxide film onto a substrate of a plasma display panel is provided. At a process for forming protective layer (8) of MgO film which is a metal oxide film, the film is formed in such a manner that partial pressure of oxygen gas or the like in evaporation room (21) which is a deposition room is within a certain range. Using this method, deposition is performed with an atmosphere in evaporation room (21) constant, so that physical properties of a film can be stabilized. As a result, a plasma display panel which can display high quality images can be manufactured.

### TECHNICAL FIELD

The present invention relates to a process for producing a plasma display panel (PDP) and more particularly to forming a film on the PDP which is known as a display apparatus characterized by its thinness, lightness and large display.

### BACKGROUND ART

In a plasma display panel (hereinafter referred to as a “PDP”), ultraviolet rays, which is generated by discharging gas, excite phosphor to emit light for an image display.

The plasma display panels are classified into two driving systems, i.e. an AC type and a DC type, and classified into two electric discharge systems, i.e. a surface discharge type and an opposed discharge type. The AC and surface discharge type PDP having a three electrodes structure is becoming a mainstream in the PDPs because of its high resolution, large screen and easiness of manufacturing. The AC and surface discharge type PDP is formed of a front substrate and a rear substrate. The front substrate includes a display electrode, which consists of a scan electrode and a sustain electrode, on a substrate such as glass, a dielectric layer covering it and a protective layer further covering it. On the other hand, the rear substrate includes a plurality of address electrodes, a dielectric layer covering it, a barrier rib on the dielectric layer, and a phosphor layer formed on the dielectric layer and sides of the barrier rib. The front substrate and the rear substrate confront each other in such a manner that the display electrode crosses over the address electrode at right angles, so that a discharge cell is formed at an intersection between the display electrode and the address electrode.

Compared with a liquid crystal panel, the PDP has the features, namely, a fast motion display, a wide view angle, easiness of manufacturing a large panel and high quality because of a self luminous type. As a result, recently, the PDP has drawn attention among flat display panels and has various uses (e.g., a display apparatus at a place where many people gather or a display apparatus for enjoying a large screen image at home).

As discussed above, on the glass substrate of the front substrate which works as a face for displaying an image, the electrodes are formed, and the dielectric layer covering them is formed. Furthermore, a magnesium oxide (MgO) film of a metal oxide film as the protective layer for covering the dielectric layer is formed. As a method for forming the protective layer made of the MgO film, an electron beam evaporation method, whose depositing rate is fast and which forms comparatively high quality MgO film, is generally used. For example, the method is disclosed on pp. 598-600 of “2001 FPD technology corpus” published by Electronic Journal Inc in Oct. 25, 2000.

However, when the magnesium oxide (MgO) film of the metal oxide film is formed, physical properties of the film sometimes change by oxygen deficiency or contamination of impurities in its deposition process.

Therefore, an atmosphere of a deposition space is controlled by introducing gas into the deposition space in the deposition process for stabilizing the physical properties of the film. However, the physical properties change depending on a state where the gas is introduced into the deposition room, so that the state of introducing gas is required to be appropriately controlled for stabilizing the physical properties of the film.

The present invention is directed to solve the problems discussed above, and therefore, it is an object to form a metal oxide film such as a high quality MgO film onto a substrate of a PDP.

### SUMMARY OF THE INVENTION

The present invention is directed to solve the problems discussed above, and aims to provide a process for producing a PDP including a process for forming a metal oxide film onto a substrate of the PDP, and partial pressure of a certain gas in a deposition room is within a certain range in a deposition process of the metal oxide film. According to the manufacturing method mentioned above, when the metal oxide film is formed onto the substrate of the PDP, the metal oxide film having high quality physical properties can be formed.

### BRIEF DESCRIPTION OF THE DRAWINGS

FIG. 1 is a sectional perspective view showing a schematic structure of a plasma display panel in accordance with an exemplary embodiment of the present invention.

FIG. 2 is a sectional view showing a schematic structure of a deposition apparatus in accordance with the exemplary embodiment of the present invention.

### DETAILED DESCRIPTION OF THE PREFERRED EMBODIMENT

A process for producing a PDP in accordance with the exemplary embodiment of the present invention is demonstrated hereinafter with reference to the accompanying drawings.

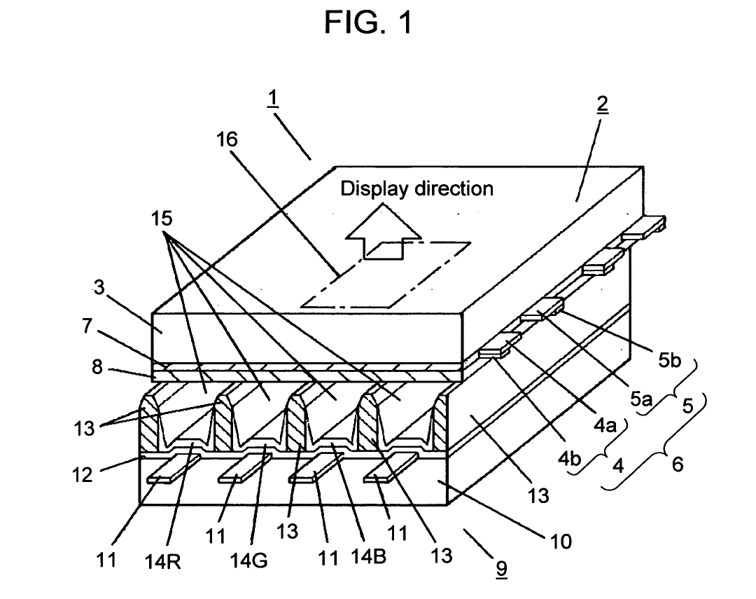

First, an example of a structure of the PDP is described. FIG. 1 is a sectional perspective view showing a schematic structure of the PDP manufactured by the manufacturing method for the PDP in accordance with an exemplary embodiment of the present invention.

Front substrate 2 of PDP 1 includes display electrode 6, which consists of scan electrode 4 and sustain electrode 5, formed on transparent and insulating substrate 3 such as glass, dielectric layer 7 covering display electrode 6, and protective layer 8 made of MgO or the like covering dielectric layer 7. In order to decrease electric resistance, scan electrode 4 is formed by laminating bus electrode 4b, which is made of a metal material such as Ag, on transparent electrode 4a. Similarly, sustain electrode 5 is formed by laminating bus electrode 5b, which is made of a metal material such as Ag, on transparent electrode 5a.

Rear substrate 9 includes address electrode 11 formed on insulating substrate 10 such as glass, dielectric layer 12 covering address electrode 11, barrier rib 13 positioned on dielectric layer 12 between adjacent address electrodes 11, and phosphor layers 14R, 14G and 14B between barrier ribs 13.

Front substrate 2 and rear substrate 9 confront each other in such a manner that display electrode 6 and address electrode 11 cross each other at right angles across barrier rib 13, so that peripheries outside image display areas are sealed by sealing members. For example, discharge gas such as Ne—Xe of 5% is sealed in discharge space 15 formed between front substrate 2 and rear substrate 9 with 66.5 kPa (500 Torr) of pressure. An intersection between display electrode 6 and address electrode 11 at discharge space 15 works as discharge cell 16 (unit emitting domain).

Next, a process for producing PDP 1 is demonstrated hereinafter with reference to FIG. 1.

For forming front substrate 2, scan electrode 4 and sustain electrode 5 are formed on substrate 3. Specifically, on substrate 3, a film made of ITO or the like is formed by a deposition process such as evaporation or sputtering. Then, patterning is performed using a photolithography method or the like, so that transparent electrodes 4a and 5a are formed. Furthermore, from above, a film made of Ag or the like is formed by a deposition process such as evaporation or sputtering. Then, patterning is performed using a photolithography method or the like, so that bus electrodes 4b and 5b are formed. Using the method discussed above, display electrode 6 which consists of scan electrode 4 and sustain electrode 5 can be obtained.

Then, display electrode 6, which is formed mentioned above, is covered with dielectric layer 7. Dielectric layer 7 is, for example, formed by screen-printing a paste containing lead-base glass material and firing. For example, a mixture of PbO (70 wt %), B₂O₃ (15 wt %), SiO₂ (10 wt %), Al₂O₃ (5wt %) and organic binder (e.g. dissolved material made by dissolving ethylcellulose of 10% in α-terpineol) is used as the paste containing lead-base glass material mentioned above. Dielectric layer 7, which is formed mentioned above, is covered with the metal oxide film, e.g. protective layer 8 made of MgO or the like.

On the other hand, for forming rear substrate 9, address electrode 11 is formed on substrate 10. Specifically, on substrate 10, a film made of Ag material or the like is formed by a deposition process such as evaporation or sputtering. Then, patterning is performed using a photolithography method or the like, so that address electrode 11 is formed. Furthermore, address electrode 11 is covered with dielectric layer 12, so that barrier rib 13 is formed.

After that, phosphor layers 14R, 14G and 14B, which are respectively made of phosphor particles of red (R), green (G) and blue (B), each is formed at a groove between barrier ribs 13. Phosphor ink in paste form, which is formed of the phosphor particles corresponding to each color and organic binder, is applied and fired for burning the organic binder. As a result, the phosphor particles are bonded, so that phosphor layers 14R, 14G and 14B are formed.

Front substrate 2 and rear substrate 9, both of which are formed discussed above, are put together in such a manner that display electrode 6 of front substrate 2 crosses over address electrode 11 of rear substrate 9 at right angles. Sealing members made of sealing glass are inserted into peripheries and fired so as to form a hermetic seal layer (not shown) for sealing. After that, discharge space 15 is exhausted to be a high vacuum, then filled with discharge gas (e.g., He—Xe base, Ne—Xe base inert gas) at certain pressure and sealed, so that PDP 1 is produced.

In the manufacturing process of PDP 1 discussed above, an example of the process for depositing protective layer 8 is demonstrated hereinafter with reference to the accompanying drawings.

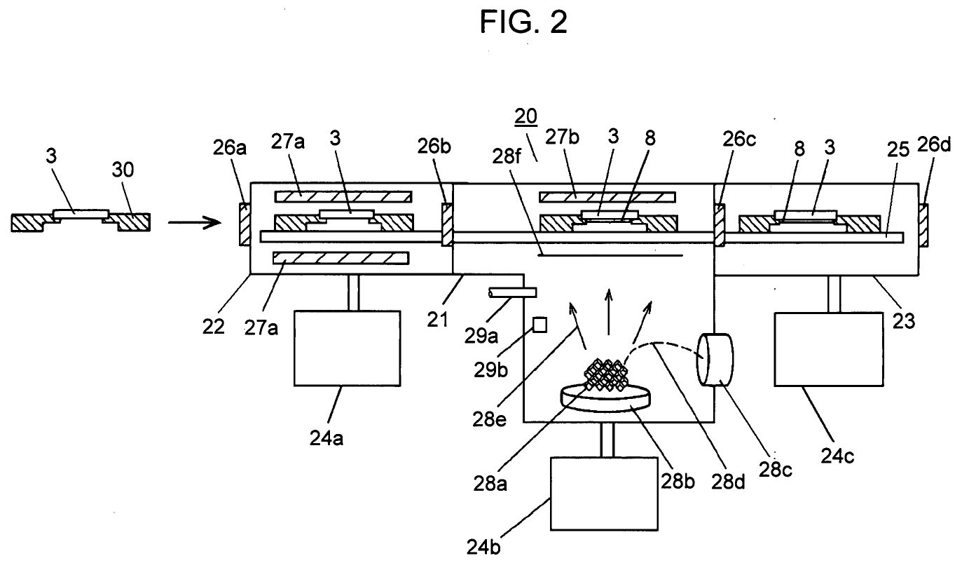

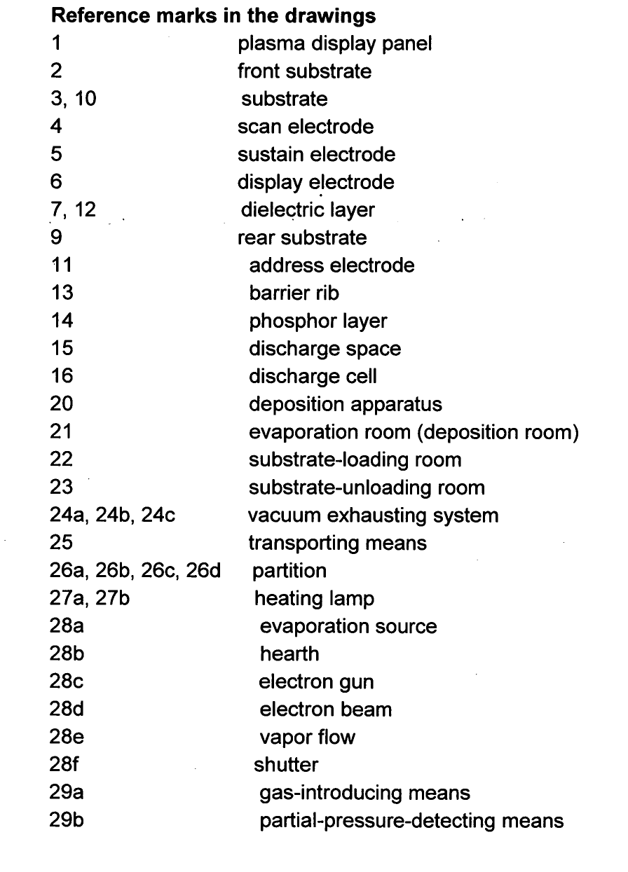

First, an example of a deposition apparatus is described hereinafter. FIG. 2 is a sectional view showing a schematic structure of deposition apparatus 20 for forming protective layer 8.

Deposition apparatus 20 includes evaporation room 21, substrate-loading room 22 and substrate-unloading room 23. Evaporation room 21 is a deposition room for forming protective layer 8 of MgO film onto substrate 3 of the PDP by evaporating MgO. Substrate-loading room 22 is a room for pre-heating substrate 3 and pre-exhausting before substrate 3 is conveyed into evaporation room 21. Substrate-unloading room 23 is a room for cooling substrate 3 after evaporation in evaporation room 21.

Substrate-loading room 22, evaporation room 21 and substrate-unloading room 23 have hermetic structures to make their inside vacuum atmospheres, and have vacuum exhausting systems 24a, 24b and 24c separately.

Transporting means 25 such as transporting roller, wire or chain is disposed through substrate-loading room 22, evaporation room 21 and substrate-unloading room 23. Openable and closable partitions 26a, 26b, 26c and 26d are respectively disposed for partitioning between the ambient air and substrate-loading room 22, between substrate-loading room 22 and evaporation room 21, between evaporation room 21 and substrate-unloading room 23, and between substrate-unloading room 23 and the ambient air. Fluctuations of vacuum degrees of substrate-loading room 22, evaporation room 21 and substrate-unloading room 23 are minimized by interlocking driving of transporting means 25 with opening and closing of partitions 26a, 26b, 26c and 26d. From the outside of the deposition apparatus, substrate 3 passes through substrate-loading room 22, evaporation room 21 and substrate-unloading room 23 in this order, and prescribed processes are performed at respective rooms. After that, substrate 3 can be unloaded out of deposition apparatus 20. Therefore, MgO can be sequentially deposited onto a plurality of substrates 3.

Heating lamps 27a and 27b for heating substrate 3 are respectively disposed at substrate-loading room 22 and evaporation room 21. Substrate 3 is generally conveyed in a state where substrate 3 is held by substrate holding jig 30.

Next, evaporation room 21 as the deposition room is described hereinafter. Hearth 28b containing MgO grains as evaporation source 28a, electron gun 28c and deflection magnet (not shown) for applying a magnetic field are disposed in evaporation room 21. Electron beam 28d irradiated from electron gun 28c is deflected by the magnetic field generated from the deflection magnet and irradiated to evaporation source 28a, so that vapor flow 28e of MgO as evaporation source 28a is generated. Generated vapor flows 28e are deposited onto a surface of substrate 3 held by substrate holding jig 30, so that protective layer 8 of MgO is formed.

Inventors of the present invention have confirmed by examinations that physical properties of the MgO film as protective layer 8 have changed by oxygen deficiency or contamination of impurities in the deposition process. For example, when oxygen is lacked or impurities such as C or H are mingled in MgO, bonding between Mg atom and O atom is disordered. In this case, it is thought that dangling bonds which are not related to bonding are generated, so that a state of secondary electron emission changes.

Therefore, for stabilizing the physical properties of the MgO film and securing characteristics of protective layer 8, the atmosphere is controlled by introducing various gases into the deposition room in the deposition process to control amount of the dangling bonds in the MgO film. In this case, oxygen gas is suitable as one of the various gases for preventing oxygen deficiency and restraining the amount of the dangling bonds. On the other hand, gas selected from the group consisting of water, hydrogen, carbon monoxide and carbon dioxide is suitable for mingling impurities such as C or H positively into the film and increasing the amount of the dangling bonds.

However, in a case where the deposition is performed by controlling the atmosphere in evaporation room 21 mentioned above, physical properties change depending on a state of gas in evaporation room 21. Therefore, a state of gas is required to be appropriately controlled for stabilizing the physical properties of the film.

Inventors of the present invention have confirmed by examinations that partial pressure of gas in evaporation room 21, especially at the deposition space, can be used as an index for controlling appropriately the state of gas at evaporation room 21 which is the deposition room, and the deposition can be performed by keeping this partial pressure within a certain range, whereby a high quality metal oxide film can be formed.

Here, the deposition space denotes a space between hearth 28b and substrate 3 in evaporation room 21. In the following description, partial pressure denotes pressure at the deposition space, and it is calculated by a ratio between an ion current value, which is measured by a quadrupole mass spectrometer, of each gas and total pressure measured by a vacuum gage.

At evaporation room 21 as the deposition room, at least one gas-introducing means 29a, which can introduce various gases for controlling the environment in evaporation room 21, is installed. For example, oxygen gas or at least one gas selected from the group consisting of water, hydrogen, carbon monoxide and carbon dioxide, or inert gas such as argon, nitrogen, helium can be introduced by gas-introducing means 29a.

In addition, evaporation room 21 includes partial-pressure-detecting means 29b and a controlling means (not shown). Partial-pressure-detecting means 29b detects the partial pressure mentioned above in evaporation room 21. The controlling means controls the amount of introducing gas from gas-introducing means 29a and the amount of exhausting gas by vacuum exhausting system 24b based on information from partial-pressure-detecting means 29b in such a manner that the partial pressure in evaporation room 21 becomes within a certain range. Using the structure discussed above, partial pressure of gas (e.g. oxygen gas or at least one gas selected from the group consisting of water, hydrogen, carbon monoxide and carbon dioxide) at the deposition space in evaporation room 21 as the deposition room can be kept within a certain range, and the metal oxide film such as MgO can be evaporated.

Next, a flow of deposition is described hereinafter. In evaporation room 21 as the deposition room, substrate 3 is heated by heating lamp 27b and kept at a certain temperature. The temperature is set approximately 100° C. to 400° C. in such a manner that display electrode 6 and dielectric layer 7, both of which have been already formed on substrate 3, do not deteriorate by the heat. Then, with shutter 28f closed, electron beam 28d is irradiated from electron gun 28c to evaporation source 28a for pre-heating, so that impure gas is removed. After that, gas is introduced from gas-introducing means 29a. As the gas in that case, for example, oxygen or gas containing oxygen can be used for preventing oxygen deficiency in the MgO film, and at least one gas selected from the group consisting of water, hydrogen, carbon monoxide and carbon dioxide can be used for mingling impurities such as C or H positively into the film.

These gases are controlled in such a manner that the partial pressure at the deposition space in evaporation room 21 becomes within a certain range. For example, while the exhausting is performed by vacuum exhausting system 24b in evaporation room 21, gas is introduced from gas-introducing means 29a, controlled and equilibrated with the amount of exhausting gas. In this state, when shutter 28f is opened, vapor flow 28e of MgO is emitted onto substrate 3. As a result, protective layer 8 of MgO film is formed on substrate 3 by vapor material which has risen to substrate 3.

When a thickness of protective layer 8 of MgO film formed on substrate 3 reaches a predetermined value (e.g. approximately 0.5 μm), shutter 28f is shut and substrate 3 is conveyed via partition 26c to substrate-unloading room 23.

The partial pressure of the oxygen gas at the deposition space in evaporation room 21 as the deposition room is preferably set within a range of 3×10⁻³ Pa to 3×10⁻² Pa because physical properties of the film particularly improve.

The partial pressure of at least one gas selected from the group consisting of water, hydrogen, carbon monoxide and carbon dioxide at the deposition space in evaporation room 21 as the deposition room are preferably set within a range of 1×10⁻⁴ Pa to 1×10⁻³ Pa in water (gas state), 1×10⁻³ Pa to 5×10⁻² Pa in hydrogen, 1×10⁻³ Pa to 5×10⁻² Pa in carbon monoxide, and 1×10⁻⁴ Pa to 3×10⁻³ Pa in carbon dioxide because physical properties of the film particularly improve.

In addition, keeping the vacuum degrees in evaporation room 21 as the deposition room within a certain range is preferable as well as keeping the partial pressure within a certain range because a depositing rate is kept constant and a high quality film can be obtained. In this case, vacuum-degree-detecting means (not shown) for detecting a vacuum degree at the deposition space can be installed in evaporation room 21 of deposition apparatus 20 shown in FIG. 2. With information from vacuum-degree-detecting means, the amount of introducing gas from gas-introducing means 29a and the amount of exhausting gas by vacuum exhausting system 24b are controlled in such a manner that the partial pressure in evaporation room 21 and the vacuum degrees become within certain ranges. In this case, as a method for controlling the vacuum degrees within a certain range, the vacuum degrees can be controlled by using inert gas such as argon, nitrogen, helium without adversely affecting physical properties of the MgO film to be deposited. Because inert gas does not act chemically on the MgO film, the vacuum degree can be controlled without adversely affecting physical properties of the MgO film.

The various gases above discussed not only denote 100% purity thereof, but also include generally obtainable gas whose purity is approximately 99.9% and which partially contains impurities for example.

Further, for example, as the structure of deposition apparatus 20, one or more substrate-heating room for heating substrate 3 may be disposed between substrate-loading room 22 and evaporation room 21 based on a condition of a temperature profile of substrate 3. In addition, one or more substrate-cooling room may be disposed between evaporation room 21 and substrate-unloading room 23.

Still further, evaporation of MgO for substrate 3 in evaporation room 2 can be operated in a state where transporting stands still or transporting works.

Yet further, deposition apparatus 20 is not limited to the structure mentioned above, and a buffer room for controlling cycle time or a chamber room for heating/cooling may be disposed between rooms. In addition, the deposition may be performed by a batch type. These structures mentioned above have the same effects as that of the present embodiment.

In addition, when a plurality of gases is introduced into evaporation room 21 as the deposition room, the following introducing methods can be used. One method is a method that gas-introducing means 29a corresponding to respective gases are installed and gases are introduced from them. Another method is a method that a mixing room (not shown) for mixing a plurality of gases is installed, and gases are mixed at it and introduced through gas-introducing mean 29a.

According to the present invention, the example that protective layer 8 is formed of MgO by evaporation is described, however, the present invention is not limited to MgO or evaporation, and the same effects can be obtained in a case where the metal oxide film is formed.

### INDUSTRIAL APPLICABILITY

According to the present invention, a process for producing a PDP, which can form a metal oxide film having high quality physical properties in a process forming the metal oxide film onto a substrate of the PDP, can be realized, so that a plasma display apparatus or the like having high display efficiency can be realized.

1. A process for producing a plasma display panel (PDP) including a process for forming a metal oxide film onto a substrate of the PDP, the method comprising:
forming the metal oxide film within a certain range in partial pressure of a certain gas in a deposition room.

2. A process for producing a plasma display panel (PDP) including a process for forming a metal oxide film onto a substrate of the PDP, the method comprising:
keeping partial pressure of a certain gas in a deposition room within a certain range, and keeping a vacuum degree in the deposition room within a certain range in depositing the metal oxide film.

3. The process for producing the PDP of claim 1,
wherein the certain gas in the deposition room is oxygen gas.

4. The process for producing the PDP of claim 3,
wherein the partial pressure of the oxygen gas is kept within a certain range by introducing the oxygen gas while the deposition room is exhausted.

5. The process for producing the PDP of claim 4,
wherein the partial pressure of the oxygen gas ranges within 1×10⁻³ Pa to 5×10⁻² Pa.

6. The process for producing the PDP of claim 1,
wherein the certain gas in the deposition room is at least one gas selected from the group consisting of water, hydrogen, carbon monoxide and carbon dioxide.

7. The process for producing the PDP of claim 6,
wherein the partial pressure of at least one gas selected from the group consisting of water, hydrogen, carbon monoxide and carbon dioxide is kept within a certain range by introducing at least the gas selected from the group consisting of water, hydrogen, carbon monoxide and carbon dioxide while the deposition room is exhausted.

8. The process for producing the PDP of claim 7,
wherein the partial pressure of the water ranges within 1×10⁻⁴ Pa to 5×10⁻³ Pa.

9. The process for producing the PDP of claim 7,
wherein the partial pressure of the hydrogen gas ranges within 1×10⁻³ Pa to 5×10⁻² Pa.

10. The process for producing the PDP of claim 7,
wherein the partial pressure of the carbon monoxide gas ranges within 1×10⁻³ Pa to 5×10⁻² Pa.

11. The process for producing the PDP of claim 7,
wherein the partial pressure of the carbon dioxide gas ranges within 1×10⁻⁴ Pa to 5×10⁻³ Pa.

12. The process for producing the PDP of claim 2,
wherein the vacuum degree is kept within a certain range by introducing an inert gas while the deposition room is exhausted.

13. An apparatus of manufacturing a plasma display panel (PDP) for forming a metal oxide film onto a substrate of the PDP, the apparatus comprising:
a deposition room;
a gas-introducing means for introducing gas into the deposition room;
an exhausting means for exhausting the deposition room;
a partial-pressure-detecting means for detecting partial pressure of the gas in the deposition room; and
a controlling means for controlling an amount of introducing gas from the gas-introducing means and an amount of exhausting gas by the exhausting means based on information of the partial pressure of the gas from the partial-pressure-detecting means in such a manner that the partial pressure of the gas in the deposition room becomes within a certain range.

14. An apparatus of manufacturing a plasma display panel (PDP) for forming a metal oxide film onto a substrate of the PDP, the apparatus comprising:
a deposition room;
a gas-introducing means for introducing gas into the deposition room;
an exhausting means for exhausting the deposition room;
a partial-pressure-detecting means for detecting partial pressure of the gas in the deposition room;
a vacuum-degree-detecting means for detecting a vacuum degree in the deposition room; and
a controlling means for controlling an amount of introducing gas from the gas-introducing means and an amount of exhausting gas by the exhausting means based on information of the partial pressure of the gas from the partial-pressure-detecting means and information of the vacuum degree from the vacuum-degree-detecting means in such a manner that the partial pressure of the gas and the vacuum degree in the deposition room become within certain ranges.

15. The apparatus of manufacturing a PDP of claim 13,
wherein the partial-pressure-detecting means detects the partial pressure of oxygen gas.

16. The apparatus of manufacturing a PDP of claim 13,
wherein the partial-pressure-detecting means detects the partial pressure of at least one gas selected from the group consisting of water, hydrogen, carbon monoxide and carbon dioxide.

17. The process for producing the PDP of claim 2,
wherein the certain gas in the deposition room is oxygen gas.

18. The process for producing the PDP of claim 2,
wherein the certain gas in the deposition room is at least one gas selected from the group consisting of water, hydrogen, carbon monoxide and carbon dioxide.

19. The apparatus of manufacturing a PDP of claim 14,
wherein the partial-pressure-detecting means detects the partial pressure of oxygen gas.

20. The apparatus of manufacturing a PDP of claim 14,
wherein the partial-pressure-detecting means detects the partial pressure of at least one gas selected from the group consisting of water, hydrogen, carbon monoxide and carbon dioxide.
